(19) United States
(12) Patent Application Publication
(10) Pub. No.: US 2026/0324177 A1
(43) Pub. Date: Oct. 15, 2026

(54) DUAL-COLOR LIGHT SOURCE STRUCTURE AND AIMING DEVICE

(71) Applicant: PSG Opto Development Co., Ltd., Shenzhen (CN)

(72) Inventor: San SU, Shenzhen (CN)

(73) Assignee: PSG Opto Development Co., Ltd., Shenzhen (CN)

(21) Appl. No.: 19/639,814

(22) Filed: Apr. 6, 2026

(30) Foreign Application Priority Data
Apr. 11, 2025 (CN) 202520681281.5

(51) Int. Cl. H10H 29/85; H10H 29/24

(52) U.S. Cl. CPC H10H 29/857; H10H 29/24

(57) ABSTRACT

A dual-color light source structure and an aiming device are provided. The dual-color light source structure includes a substrate, a first light-emitting chip disposed on the substrate and electrically connected to the substrate, and a second light-emitting chip disposed on the first light-emitting chip and electrically connected to both the substrate and the first light-emitting chip. The first light-emitting chip and the second light-emitting chip emit light of different colors. The first light-emitting chip provides range indication, and the second light-emitting chip provides aiming point indication.

### CROSS-REFERENCE TO RELATED APPLICATIONS

The present application claims priority to Chinese Patent Application No. 202520681281.5, filed on Apr. 11, 2025, the content of all of which is incorporated herein by reference.

### FIELD

The present application relates to the field of light source technology of aiming device, and in particular to a dual-color light source structure and an aiming device.

### BACKGROUND

Conventional aiming devices typically employ monochromatic (e.g., red light or green light) illumination patterns to indicate a shooting target, which are generally suitable for simple aiming point indication scenarios. In certain applications, particularly where clear differentiation between a target range and a precise aiming point is required, existing technologies often generate two different illumination patterns through Light-Emitting Diode (LED) devices to respectively represent the target range and the aiming point. However, since such LED devices are generally limited to emitting light with a single color, the distinction between the range indication and the aiming point indication is often insufficient, resulting in suboptimal target recognition and failing to meet the demands for more precise and efficient aiming.

To improve indication performance, some approaches employ color Organic Light-Emitting Diode (OLED) micro-displays to distinguish between range indication and aiming point indication using different colors. Although OLED displays may provide improved visual performance, they still present several drawbacks. For example, OLED devices may exhibit limited environmental robustness and may be susceptible to temperature, humidity, and other environmental factors, which may reduce service life. In addition, OLED displays typically require relatively complex driving systems, resulting in higher costs and increased difficulty in maintenance and replacement, thereby increasing overall product cost and maintenance burden.

Accordingly, there remains a need for an aiming device capable of providing clear differentiation between a target range and an aiming point while maintaining relatively low cost and improving reliability and durability.

### SUMMARY

In view of the shortcomings of the prior art, the purpose of the present application is to provide a dual-color light source structure and an aiming device, which is directed to addressing the issues of high cost and poor environmental stability associated with dual-color light source structures in conventional aiming devices.

The technical solution adopted by the present application to solve the technical problem is as follows: A dual-color light source structure adopted in an aiming device, which includes:

a substrate;

a first light-emitting chip disposed on the substrate and electrically connected to the substrate;

a second light-emitting chip disposed on the first light-emitting chip and electrically connected to both the substrate and the first light-emitting chip; and

the first light-emitting chip and second light-emitting chip emit light of different colors, the first light-emitting chip is used to provide range indication, and the second light-emitting chip is used to provide aiming point indication.

In an embodiment, a first chip soldering area, a first electrode soldering area, and a second electrode soldering area are arranged on the substrate; the first light-emitting chip is soldered to the first chip soldering area;

a second chip soldering area, a first inner lead soldering area, and a second inner lead soldering area are arranged on an end surface of the first light-emitting chip away from the substrate;

the second light-emitting chip is soldered to the second chip soldering area, a bonding area is arranged on an end surface of the second light-emitting chip away from the first light-emitting chip; and

the first inner lead soldering area is electrically connected to the first electrode soldering area, the bonding area is electrically connected to the second inner lead soldering area, and the second inner lead soldering area is electrically connected to the second electrode soldering area.

In an embodiment, the dual-color light source structure further includes:

a first bonding wire electrically connecting the first inner lead soldering area and the first electrode soldering area;

a second bonding wire electrically connecting the bonding area and the second inner lead soldering area; and

a third bonding wire electrically connecting the second inner lead soldering area and the second electrode soldering area.

In an embodiment, the dual-color light source structure further includes connecting layer electrically connecting the first light-emitting chip and the second light-emitting chip.

In an embodiment, the first light-emitting chip includes, from bottom to top, a first P-side metal layer, a first P-type substrate, a first bonding layer, a first P-type doped layer, a first N-type doped layer, and a first N-side metal layer;

the second light-emitting chip includes, from bottom to top, a second N-side metal layer, a second N-type substrate, a second N-type doped layer, a second P-type doped layer, and a second P-side metal layer; and

the connecting layer is located between the first N-side metal layer and the second N-side metal layer, a first PN junction is formed between the first P-type doped layer and the first N-type doped layer, and a second PN junction is formed between the second P-type doped layer and the second N-type doped layer; the second chip soldering area, the first inner lead soldering area, and the second inner lead soldering area are all disposed on the first N-side metal layer.

In an embodiment, the first light-emitting chip includes, from bottom to top, a third N-side metal layer, a third N-type substrate, a third N-type doped layer, a third P-type doped layer, and a third P-side metal layer;

the second light-emitting chip includes, from bottom to top, a fourth P-side metal layer, a fourth P-type substrate, a fourth bonding layer, a fourth P-type doped layer, a fourth N-type doped layer, and a fourth N-side metal layer; and

the connecting layer is located between the third P-side metal layer and the fourth P-side metal layer, a third PN junction is formed between the third P-type doped layer and the third N-type doped layer, and a fourth PN junction is formed between the fourth P-type doped layer and the fourth N-type doped layer.

In an embodiment, the first light-emitting chip has a first light-emitting pattern, the second light-emitting chip has a second light-emitting pattern, and the second light-emitting pattern is located within the first light-emitting pattern; and

the second bonding wire is located within the first light-emitting pattern, the first bonding wire and the third bonding wire are each provided in a through-hole configuration, and the first bonding wire, the second bonding wire, and the third bonding wire do not block the first light-emitting pattern.

In an embodiment, the second light-emitting pattern is configured as a central arrow shape, an auxiliary dot shape, a horseshoe-shaped ring, or a central dot shape; and the first light-emitting pattern is configured as a circular shape, an arc shape, or a crosshair shape.

In an embodiment, the first light-emitting chip emits light in any one of red, green, or blue, the second light-emitting chip emits light in any one of red, green, or blue, and the first light-emitting chip and the second light-emitting chip emit light of different colors.

Another technical solution adopted by the present application to solve the technical problem is an aiming device, which includes the dual-color light source structure as described above.

Beneficial effects:

The present application provides a dual-color light source structure and an aiming device. The dual-color light source structure employs two light-emitting chips emitting light of different colors, which are respectively used for range indication and aiming point indication. In this manner, the target range and the aiming point may be visually distinguished more clearly, enabling a user to more quickly and accurately identify a target, thereby improving the target recognition experience of the aiming device. In addition, the dual-color light source structure is implemented by stacking the two light-emitting chips on a same substrate, which may simplify the light source configuration and the manufacturing process. Compared with conventional solutions such as color OLED displays or arrangements of multiple discrete light-emitting chips, the chip stacked package configuration may reduce process complexity, facilitate mass production, and lower manufacturing cost. Moreover, the structure may be compatible with existing product requirements, thereby lowering the cost significantly and avoiding the need for high-cost driving systems and complex circuit designs to adapt to market demands. Furthermore, LED chips generally exhibit relatively strong resistance to interference and long service life. By adopting the chip stacked package configuration, the dual-color light source structure may achieve improved structural reliability and stable operation under relatively harsh environmental conditions, thereby overcoming limitations associated with OLED technologies, such as limited environmental adaptability and shorter service life. Accordingly, the disclosed dual-color light source structure may provide improved performance while reducing manufacturing and operational costs, thereby enhancing the overall cost-performance ratio of the product.

### BRIEF DESCRIPTION OF THE DRAWINGS

FIG. 1 is a cross-sectional schematic diagram of a dual-color light source structure according to the present application;

FIG. 2 is a cross-sectional schematic diagram of a dual-color light source structure according to another embodiment of the present application;

FIG. 3 is a cross-sectional schematic diagram of a dual-color light source structure according to yet another embodiment of the present application;

FIG. 4 is a schematic diagram of a light emission pattern of a dual-color light source structure according to the present application; and

FIG. 5 is a schematic diagram of another light-emitting pattern of the dual-color light source structure according to the present application.

### DETAILED DESCRIPTION OF THE EMBODIMENTS

To make the objectives, technical solutions, and advantages of the present application clearer and more explicit, the following detailed description of the present application is provided with reference to the accompanying drawings and embodiments. It should be understood that the embodiments described herein are merely illustrative of the present application and are not intended to limit the present application.

In the description of the present application, it should be understood that the terms “center”, “longitudinal”, “lateral”, “upper”, “lower”, “front”, “rear”, “left”, “right”, “vertical”, “horizontal”, “top”, “bottom”, “inner”, and “outer”, etc., indicating orientation or positional relationships based on the orientation or positional relationships shown in the accompanying drawings, are used only for the convenience of describing the present application and simplifying the description, and do not indicate or imply that the device or element referred to must have a specific orientation, or be constructed and operated in a specific orientation, and therefore should not be construed as a limitation on the present application. Furthermore, the terms “first” and “second” are used for descriptive purposes only and should not be construed as indicating or implying relative importance or implicitly specifying the number of indicated technical features. Thus, a feature defined as “first” or “second” may explicitly or implicitly include one or more of that feature. In the description of the present application, unless otherwise stated, “a plurality of” refers to two or more.

In the description of the present application, it should be noted that, unless otherwise expressly specified and limited, the terms “installation”, “connection”, and “connect” should be interpreted broadly. For example, they may refer to a fixed connection, a detachable connection, or an integral connection; they may refer to a mechanical connection or an electrical connection; they may refer to a direct connection or an indirect connection through an intermediate medium; and they may refer to the internal connection between two components. Those skilled in the art can understand the specific meaning of the above terms in the present application based on the specific circumstances.

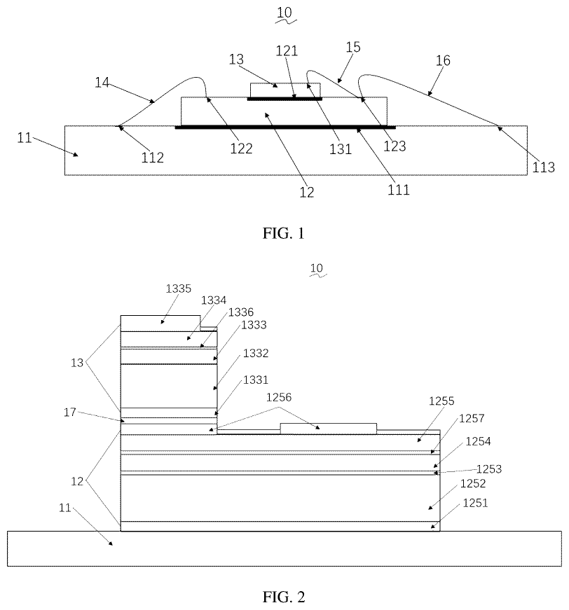

Referring to FIG. 1, the first embodiment of the present application provides a dual-color light source structure 10. The dual-color light source structure 10 is adopted in an aiming device, enabling the aiming device to provide range indication and aiming point indication, and the range indication and aiming point indication refer to different colors. The dual-color light source structure 10 includes a substrate 11, a first light-emitting chip 12, and a second light-emitting chip 13. The substrate 11, the first light-emitting chip 12, and the second light-emitting chip 13 are stacked sequentially from bottom to top. The first light-emitting chip 12 is disposed on the substrate 11 and is electrically connected to the substrate 11. The second light-emitting chip 13 is disposed on the first light-emitting chip 12 and is electrically connected to both the substrate 11 and the first light-emitting chip 12. At the same time, the light emitted from the first light-emitting chip 12 and the light emitted from the second light-emitting chip 13 are set to different colors. The first light-emitting chip 12 is adopted to provide range indication, and the second light-emitting chip 13 is adopted to provide aiming point indication.

By incorporating two light-emitting chips that emit light of different colors, one for range indication and the other for aiming point indication, the target range and aiming point are effectively distinguished visually, enabling users to quickly and accurately identify the aiming target and improving the target identification experience of the aiming device. Simultaneously, the dual-color light source structure 10 simplifies the light source structure and manufacturing process by stacking the two light-emitting chips on the same substrate 11. Compared to conventional color OLED displays or combinations of multiple individual light-emitting chips, the dual-color light-emitting chip provides a stacked package configuration that is simpler, easier to mass-produce, reduces the complexity and cost of the production process, and is compatible with existing product requirements, thus significantly reducing product costs while avoiding high-cost drive systems and complex circuit designs. This allows it to better adapt to market demands. Furthermore, LED chips themselves show strong anti-interference capabilities and a long lifespan. The use of light-emitting chip stacked package configuration ensures that the dual-color light source structure 10 provided in the present application not only has high structural reliability but also operates stably under more severe environmental conditions, overcoming the shortcomings of OLED technology in terms of poor environmental adaptability and short lifespan. Ultimately, the dual-color light source structure 10 not only has high performance but also improves the product's cost-effectiveness while reducing costs for production and usage.

In some embodiments, the substrate 11 is provided with a first chip soldering area 111, a first electrode soldering area 112, and a second electrode soldering area 113; thereby providing a stable mounting point for the first light-emitting chip 12, and ensuring that the first light-emitting chip 12 and the second light-emitting chip 13 are firmly connected to the substrate 11 and the circuit, simplifying the electrical connection, improving the efficiency of the soldering process, and reducing the problem of unstable light source caused by poor contact. The first light-emitting chip 12 is soldered to the first chip soldering area 111, ensuring that the LED chip for range indicator is firmly fixed on the substrate 11, guaranteeing good electrical connection. The first light-emitting chip 12 is provided with a second chip soldering area 121, a first inner lead soldering area 122, and a second inner lead soldering area 123 on an end surface of the first light-emitting chip 12 away from the substrate 11. The second light-emitting chip 13 is soldered to the second chip soldering area 121, and a bonding area 131 is provided on an end surface of the second light-emitting chip 13 away from the first light-emitting chip 12. The first inner lead soldering area 122 is electrically connected to the first electrode soldering area 112, the bonding area 131 is electrically connected to the second inner lead soldering area 123, and the second inner lead soldering area 123 is electrically connected to the second electrode soldering area 113. This achieves a stable stacking between the first light-emitting chip 12 and the second light-emitting chip 13, ensuring a stable electrical connection between the second light-emitting chip 13 and the first light-emitting chip 12, and avoiding the risks caused by relative chip displacement in traditional planar arrangement methods. In addition, the stacking method makes the dual-color light source structure 10 more compact, reduces manufacturing costs, and ensures good performance of the product in complex environments, improving the overall performance and market competitiveness of the dual-color light source structure 10.

In some embodiments, the dual-color light source structure 10 further includes a first bonding wire 14, a second bonding wire 15, and a third bonding wire 16. The first bonding wire 14 electrically connects the first inner lead soldering area 122 and the first electrode soldering area 112, thereby ensuring the stability of current transmission, reducing the risk of poor contact, ensuring the normal operation and stable light emission of the LED chip for range indicator, and improving the reliability of the dual-color light source structure 10. The second bonding wire 15 electrically connects the bonding area 131 and the second inner lead soldering area 123. The second bonding wire 15 optimizes the electrical connection of the LED chip for target indicator, ensuring the stability in practical application, stabilizing the light emission effect of the target indicator LED chip, and further improving the reliability of the dual-color light source structure 10. The third bonding wire 16 electrically connects the second inner lead soldering area 123 and the second electrode soldering area 113. The third bonding wire 16 optimizes the current transmission path, ensures the current conduction efficiency between the second light-emitting chip 13 and the substrate 11, reduces the performance degradation caused by unstable electrical connection, and enhances the stability and service life of the dual-color light source structure 10. It should be noted that the second light-emitting chip 13 and the first light-emitting chip 12 are electrically connected to the substrate 11 by the second bonding wire 15 and the third bonding wire 16.

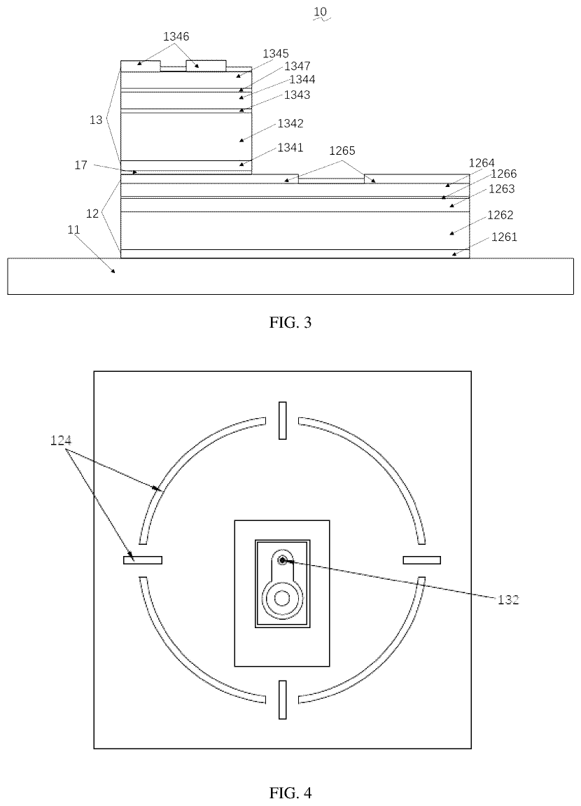

Referring to FIG. 2 and FIG. 3, in some embodiments, the dual-color light source structure 10 further includes a connecting layer 17. The connecting layer 17 electrically connects the first light-emitting chip 12 and the second light-emitting chip 13. The addition of the connecting layer 17 not only strengthens the electrical connection between the two light-emitting chips, but also improves the stability and efficiency of the light source structure. The connecting layer 17 may be made of conductive material (such as metal or conductive polymer), and the two chips may be connected together by soldering, pressing or other appropriate connection processes.

In some embodiments, the first light-emitting chip 12 includes, from bottom to top, a first P-side metal layer 1251, a first P-type substrate 1252, a first bonding layer 1253, a first P-type doped layer 1254, a first N-type doped layer 1255, and a first N-side metal layer 1256. The second light-emitting chip 13 includes, from bottom to top, a second N-side metal layer 1331, a second N-type substrate 1332, a second N-type doped layer 1333, a second P-type doped layer 1334, and a second P-side metal layer 1335. The connecting layer 17 is located between the first N-side metal layer 1256 and the second N-side metal layer 1331, a first PN junction 1257 is formed between the first P-type doped layer 1254 and the first N-type doped layer 1255, and a second PN junction 1336 is formed between the second P-type doped layer 1334 and the second N-type doped layer 1333. The connecting layer 17 improves the stability and efficiency of current transmission, ensuring a good electrical connection between the first light-emitting chip 12 and the second light-emitting chip 13. Simultaneously, the placement of the soldering areas simplifies the manufacturing process, reduces the risk of poor contact, and enhances the overall reliability of the light source structure. It should be noted that in the present embodiment, the first light-emitting chip 12 is a light-emitting chip of green light range indicator, and the second light-emitting chip 13 is a light-emitting chip of red light target indicator.

In some embodiments, the first light-emitting chip 12 includes, from bottom to top, a third N-side metal layer 1261, a third N-type substrate 1262, a third N-type doped layer 1263, a third P-type doped layer 1264, and a third P-side metal layer 1265. The second light-emitting chip 13 includes, from bottom to top, a fourth P-side metal layer 1341, a fourth P-type substrate 1342, a fourth bonding layer 1343, a fourth P-type doped layer 1344, a fourth N-type doped layer 1345, and a fourth N-side metal layer 1346. The connecting layer 17 is located between the third P-side metal layer 1265 and the fourth P-side metal layer 1341, a third PN junction 1266 is formed between the third P-type doped layer 1264 and the third N-type doped layer 1263, and a fourth PN junction 1347 is formed between the fourth P-type doped layer 1344 and the fourth N-type doped layer 1345. The connecting layer 17 optimizes the electrical connection between the first light-emitting chip 12 and the second light-emitting chip 13, ensuring the stability of current conduction and the high efficiency of light emission. At the same time, the reasonable placement of the soldering areas makes the soldering process simpler and effectively avoids instability caused by poor contact. It should be noted that in the present embodiment, the first light-emitting chip 12 is a light-emitting chip of red light range indicator and the second light-emitting chip 13 is a light-emitting chip of green light target indicator.

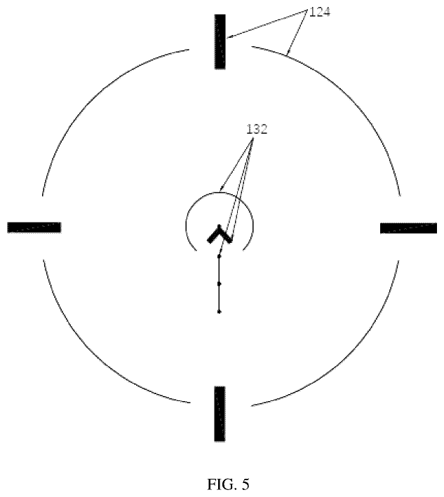

Referring to FIG. 4 and FIG. 5, in some embodiments, the first light-emitting chip 12 has a first light-emitting pattern 124, and the second light-emitting chip 13 has a second light-emitting pattern 132, with the second light-emitting pattern 132 located within the first light-emitting pattern 124. The first light-emitting pattern 124 is a range indication pattern designed to provide a clear range indication function, while the second light-emitting pattern 132 indicates the aiming point or target position. The first light-emitting pattern 124 helps improve the visibility and clarity of the range indication, enabling users to intuitively identify the target range and improving the overall accuracy of the aiming device. The second light-emitting pattern 132 not only clearly indicates the aiming point but also forms a sense of hierarchy with the first light-emitting pattern 124 through their positional relationship, enhancing the visual effect and user recognition experience, helping users to quickly and accurately determine the shooting target, and improving the efficiency and accuracy of aiming. Since the second light-emitting pattern 132 is located within the first light-emitting pattern 124, the light-emitting patterns of the two light-emitting chips are interconnected and coordinated, maximizing the utilization of the light source distribution and space, making the entire dual-color light source structure 10 more compact and efficient.

In some embodiments, the second bonding wire 15 is located within the first light-emitting pattern 124, and the first bonding wire 14 and the third bonding wire 16 are each provided in a through-hole configuration, ensuring that the first bonding wire 14, the second bonding wire 15, and the third bonding wire 16 do not block the first light-emitting pattern 124. This effectively prevents the first bonding wire 14, the second bonding wire 15, and the third bonding wire 16 from blocking the range indicator pattern, further improving the indicating effect of the dual-color light source structure 10 and the aiming device.

Furthermore, the second light-emitting pattern 132 is configured as a central arrow shape, an auxiliary dot shape, a horseshoe-shaped ring, or a central dot shape, and the first light-emitting pattern 124 is configured as a circular shape, an arc shape, or a crosshair shape. Thus, the first light-emitting pattern 124 and the second light-emitting pattern 132 may vary according to different scenario requirements, thereby expanding the applicability of the dual-color light source structure 10.

In some embodiments, the first light-emitting chip 12 emits light in any one of red, green, or blue, and the second light-emitting chip 13 emits light in any one of red, green, or blue, with the first light-emitting chip 12 and the second light-emitting chip 13 emitting light of different colors. This flexible selection of red, green, or blue light colors, while ensuring the different colors of the first light-emitting chip 12 and the second light-emitting chip 13, significantly improves the differentiation between range indication and aiming point indication, enabling users to quickly and accurately identify shooting targets in complex environments, thus enhancing the adaptability, accuracy, and overall performance of the light source.

In a second embodiment of the present application, an aiming device is further provided, which includes the dual-color light source structure 10 as described in the first embodiment of the present application. It is understood that a high-performance, high-reliability aiming device is provided, capable of providing accurate and clear aiming point indication in various environments, improving the stability, service life, and applicability of the aiming device. The dual-color light source structure 10 gives the aiming device excellent visual effects and target recognition performance, meeting the market demands for efficient and reliable aiming equipment.

In summary, the present application provides a dual-color light source structure and an aiming device. The dual-color light source structure is adopted in an aiming device and includes: a substrate; a first light-emitting chip disposed on the substrate and electrically connected to the substrate; and a second light-emitting chip disposed on the first light-emitting chip and electrically connected to both the substrate and the first light-emitting chip. The first light-emitting chip and the second light-emitting chip emit light of different colors. The first light-emitting chip provides range indication, and the second light-emitting chip provides aiming point indication. Therefore, the target range and the aiming point may be visually distinguished more clearly, enabling a user to more quickly and accurately identify a target, thereby improving the target recognition experience of the aiming device. In addition, the dual-color light source structure is implemented by stacking the two light-emitting chips on a same substrate, which may simplify the light source configuration and the manufacturing process. Compared with conventional solutions such as color OLED displays or arrangements of multiple discrete light-emitting chips, the chip stacked package configuration may reduce process complexity, facilitate mass production, and lower manufacturing cost. Moreover, the structure may be compatible with existing product requirements, thereby lowering the cost significantly and avoiding the need for high-cost driving systems and complex circuit designs to adapt to market demands. Furthermore, light-emitting diode (LED) chips generally exhibit relatively strong resistance to interference and long service life. By adopting the chip stacked package configuration, the dual-color light source structure may achieve improved structural reliability and stable operation under relatively harsh environmental conditions, thereby overcoming limitations associated with OLED technologies, such as limited environmental adaptability and shorter service life. Accordingly, the disclosed dual-color light source structure may provide improved performance while reducing manufacturing and operational costs, thereby enhancing the overall cost-performance ratio of the product.

It should be understood that the present application is not limited to the embodiments above. Those skilled in the art may make improvements or modifications based on the above description, and all such improvements and modifications should fall within the protection scope of the appended claims.

What is claimed is:

1. A dual-color light source structure, adopted in an aiming device, comprising:
a substrate;
a first light-emitting chip disposed on the substrate, the first light-emitting chip electrically connected to the substrate; and
a second light-emitting chip disposed on the first light-emitting chip, the second light-emitting chip electrically connected to both the substrate and the first light-emitting chip;
wherein the first light-emitting chip and second light-emitting chip emit light of different colors, the first light-emitting chip is configured to provide range indication, and the second light-emitting chip is configured to provide aiming point indication.

2. The dual-color light source structure according to claim 1, wherein
a first chip soldering area, a first electrode soldering area, and a second electrode soldering area are arranged on the substrate, and the first light-emitting chip is soldered to the first chip soldering area;
a second chip soldering area, a first inner lead soldering area, and a second inner lead soldering area are arranged on an end surface of the first light-emitting chip away from the substrate;
the second light-emitting chip is soldered to the second chip soldering area, and a bonding area is arranged on an end surface of the second light-emitting chip away from the first light-emitting chip; and
the first inner lead soldering area is electrically connected to the first electrode soldering area, the bonding area is electrically connected to the second inner lead soldering area, and the second inner lead soldering area is electrically connected to the second electrode soldering area.

3. The dual-color light source structure according to claim 2, further comprising:
a first bonding wire electrically connecting the first inner lead soldering area and the first electrode soldering area;
a second bonding wire electrically connecting the bonding area and the second inner lead soldering area; and
a third bonding wire electrically connecting the second inner lead soldering area and the second electrode soldering area.

4. The dual-color light source structure according to claim 2, further comprising:
a connecting layer electrically connecting the first light-emitting chip and the second light-emitting chip.

5. The dual-color light source structure according to claim 4, wherein
the first light-emitting chip comprises, from bottom to top, a first P-side metal layer, a first P-type substrate, a first bonding layer, a first P-type doped layer, a first N-type doped layer, and a first N-side metal layer;
the second light-emitting chip comprises, from bottom to top, a second N-side metal layer, a second N-type substrate, a second N-type doped layer, a second P-type doped layer, and a second P-side metal layer; and
the connecting layer is located between the first N-side metal layer and the second N-side metal layer, a first PN junction is formed between the first P-type doped layer and the first N-type doped layer, and a second PN junction is formed between the second P-type doped layer and the second N-type doped layer;
wherein the second chip soldering area, the first inner lead soldering area, and the second inner lead soldering area are all disposed on the first N-side metal layer.

6. The dual-color light source structure according to claim 4, wherein
the first light-emitting chip comprises, from bottom to top, a third N-side metal layer, a third N-type substrate, a third N-type doped layer, a third P-type doped layer, and a third P-side metal layer;
the second light-emitting chip comprises, from bottom to top, a fourth P-side metal layer, a fourth P-type substrate, a fourth bonding layer, a fourth P-type doped layer, a fourth N-type doped layer, and a fourth N-side metal layer; and
the connecting layer is located between the third P-side metal layer and the fourth P-side metal layer, a third PN junction is formed between the third P-type doped layer and the third N-type doped layer, and a fourth PN junction is formed between the fourth P-type doped layer and the fourth N-type doped layer;
wherein the second chip soldering area, the first inner lead soldering area, and the second inner lead soldering area are all disposed on the third P-side metal layer.

7. The dual-color light source structure according to claim 3, wherein the first light-emitting chip has a first light-emitting pattern, the second light-emitting chip has a second light-emitting pattern, and the second light-emitting pattern is located within the first light-emitting pattern; and
the second bonding wire is located within the first light-emitting pattern, the first bonding wire and the third bonding wire are each provided in a through-hole configuration, and the first bonding wire, the second bonding wire, and the third bonding wire do not block the first light-emitting pattern.

8. The dual-color light source structure according to claim 7, wherein the second light-emitting pattern is configured as a central arrow shape, an auxiliary dot shape, a horseshoe-shaped ring, or a central dot shape, and
the first light-emitting pattern is configured as a circular shape, an arc shape, or a crosshair shape.

9. The dual-color light source structure according to claim 1, wherein the first light-emitting chip emits light in any one of red, green, or blue, and the second light-emitting chip emits light in any one of red, green, or blue, wherein the first light-emitting chip and the second light-emitting chip emit light of different colors.

10. An aiming device, comprising the dual-color light source structure according to claim 1.
